(19) United States
(12) Patent Application Publication
(10) Pub. No.: US 2025/0112039 A1
(43) Pub. Date: Apr. 3, 2025

(54) SEAM-FREE SINGLE OPERATION AMORPHOUS SILICON GAP FILL

(71) Applicant: Applied Materials, Inc., Santa Clara, CA (US)

(72) Inventors: John Bae, Pleasanton, CA (US); Praket Prakash Jha, San Jose, CA (US); Shuchi Sunil Ojha, Sunnyvale, CA (US); Jingmei Liang, San Jose, CA (US)

(73) Assignee: Applied Materials, Inc., Santa Clara, CA (US)

(21) Appl. No.: 18/376,057

(22) Filed: Oct. 3, 2023

(51) Int. Cl. H01L 21/02; H01L 21/3065

(52) U.S. Cl. CPC H01L 21/02274; H01L 21/02211; H01L 21/3065

(57) ABSTRACT

Exemplary semiconductor processing methods may include providing a silicon-containing precursor to a processing region of a semiconductor processing chamber. A substrate including one or more features may be housed within the processing region. The methods may include providing a hydrogen-containing precursor to the processing region of the semiconductor processing chamber. The methods may include forming plasma effluents of the silicon-containing precursor and the hydrogen-containing precursor. The methods may include depositing a silicon-containing material on the substrate. The silicon-containing material may extend into the one or more features.

### TECHNICAL FIELD

The present technology relates to semiconductor processing. More specifically, the present technology relates to methods of depositing material in features defining gaps on substrates.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations, a material may be formed or deposited to fill a trench or other feature formed on a semiconductor substrate. As features may be characterized by higher aspect ratios and reduced critical dimensions, these filling operations may be challenged. For example, as the deposition may occur at the top and along sidewalls of the feature, continued deposition may pinch off the feature including between sidewalls within the feature, and may produce voids within the feature. This can impact device performance and subsequent processing operations.

Thus, there is a need for improved systems and methods that can be used to produce high quality devices and structures. These and other needs are addressed by the present technology.

### SUMMARY

Exemplary semiconductor processing methods may include providing a silicon-containing precursor to a processing region of a semiconductor processing chamber. A substrate including one or more features may be housed within the processing region. The methods may include providing a hydrogen-containing precursor to the processing region of the semiconductor processing chamber. The methods may include forming plasma effluents of the silicon-containing precursor and the hydrogen-containing precursor. The methods may include depositing a silicon-containing material on the substrate. The silicon-containing material may extend into the one or more features.

In some embodiments, the silicon-containing precursor may be or include silane (SiH₄), disilane (Si₂H₆), or trisilane (Si₃H₈). The one or more features may be characterized by a critical dimension of less than or about 50 nm. The hydrogen-containing precursor may be or include diatomic hydrogen (H₂). A flow rate ratio of the silicon-containing precursor relative to the hydrogen-containing precursor may be less than or about 1:8. The plasma effluents of the silicon-containing precursor and the hydrogen-containing precursor may be formed at a plasma power of less than or about 500 W. The methods may include applying a bias power while forming plasma effluents of the silicon-containing precursor and the hydrogen-containing precursor, while depositing the silicon-containing material on the substrate, or both. The bias power may be greater than or about 250 W. The silicon-containing material may be amorphous silicon. A pressure in the semiconductor processing chamber may be maintained at less than or about 5 Torr.

Some embodiments of the present technology may encompass semiconductor processing methods. The methods may include providing a silicon-containing precursor to a processing region of a semiconductor processing chamber. A substrate including one or more features may be housed within the processing region. The methods may include providing a hydrogen-containing precursor to the processing region of the semiconductor processing chamber. A flow rate ratio of the silicon-containing precursor relative to the hydrogen-containing precursor may be less than or about 1:8. The methods may include forming plasma effluents of the silicon-containing precursor and the hydrogen-containing precursor. The methods may include depositing a silicon-containing material on the substrate. The silicon-containing material may extend into the one or more features.

In some embodiments, a flow rate of the silicon-containing precursor may be less than or about 400 sccm. Forming plasma effluents of the silicon-containing precursor and the hydrogen-containing precursor may include applying a source power to a pedestal supporting the substrate. The methods may include applying a bias power to a pedestal supporting the substrate. The bias power may be pulsed at a duty cycle less than or about 25%. The methods may include etching silicon-containing material from sidewalls of the one or more features with the plasma effluents of the hydrogen-containing precursor while depositing the silicon-containing material on the substrate. Depositing the silicon-containing material on the substrate may fill the one or more features in a single operation. The methods may include converting the silicon-containing material to a silicon-and-oxygen-containing material, a silicon-and-carbon-containing material, or a silicon-and-nitrogen-containing material.

Some embodiments of the present technology may encompass semiconductor processing methods. The methods may include providing a silicon-containing precursor to a processing region of a semiconductor processing chamber. A substrate including one or more features may be housed within the processing region. The methods may include providing a hydrogen-containing precursor to the processing region of the semiconductor processing chamber. The methods may include forming plasma effluents of the silicon-containing precursor and the hydrogen-containing precursor. The methods may include applying a bias power to a pedestal supporting the substrate. The methods may include depositing amorphous silicon on the substrate. The amorphous silicon may extend into the one or more features.

In some embodiments, the bias power may be greater than or about a source power used to form plasma effluents of the silicon-containing precursor and the hydrogen-containing precursor. The processing region may be maintained halogen-free while depositing the amorphous silicon on the substrate.

Such technology may provide numerous benefits over conventional systems and techniques. For example, by providing a hydrogen-containing precursor during deposition and/or balancing other processing conditions, silicon-containing material may deposit at a bottom of a feature while being etched from a sidewall and/or top of the feature, which may allow seam-free gap filling of the feature. Additionally, by simultaneously etching material from the sidewall and/or top of the feature, a single operation may fill the feature without cycling the deposition with etch operations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a processing method according to some embodiments of the present technology.

FIGS. 3A-3C show schematic cross-sectional views of a substrate during a processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Silicon-containing materials, such as amorphous silicon, may be used in semiconductor device manufacturing for a number of structures and processes, including as a sacrificial material, for example as a dummy gate material, or as a trench fill material. In some gap filling operations, processing may utilize plasma-enhanced deposition under process conditions to increase the directionality of the deposition, which may allow the deposited material to better fill features on the substrate. In other gap filling operations, processing may utilize flowable films under process conditions to avoid the formation of seams and/or voids in the deposited material.

As feature sizes continue to shrink, plasma-enhanced depositions may be challenged for narrow features, which may be further characterized by higher aspect ratios. For example, pinching of the feature may more readily occur due to deposition on sidewalls of the feature, which in small feature sizes may further restrict flow and deposition further into the feature, and may produce seams or voids in the deposited material. Conventional technologies have attempted to address the formation of seams or voids by performing intermittent etch operations to remove materials from the sidewalls of the features being filled. However, conventional etch operations have required many cycles to limit seam or void formation. Alternatively, conventional technologies have attempted to use flowable films. However, flowable films may form a porous material that cannot withstand subsequent integration processing, such as etching or ashing operations. Additionally, flowable films may be prone to shrinkage during curing operations, which may damage the structure or result in void formation.

The present technology may overcome these limitations by performing a simultaneous etch of the deposited material while performing bottom-up gap filling. The simultaneous etch may be achieved by providing an etchant precursor, such as a hydrogen-containing precursor, with the deposition precursor(s). The etchant precursor may preferentially remove lower quality sidewall and/or top material over the higher quality bottom material.

After describing general aspects of a chamber according to some embodiments of the present technology in which plasma processing operations discussed below may be performed, specific methodology may be discussed. It is to be understood that the present technology is not intended to be limited to the specific films, chambers, or processing discussed, as the techniques described may be used to improve a number of film formation processes, and may be applicable to a variety of processing chambers and operations.

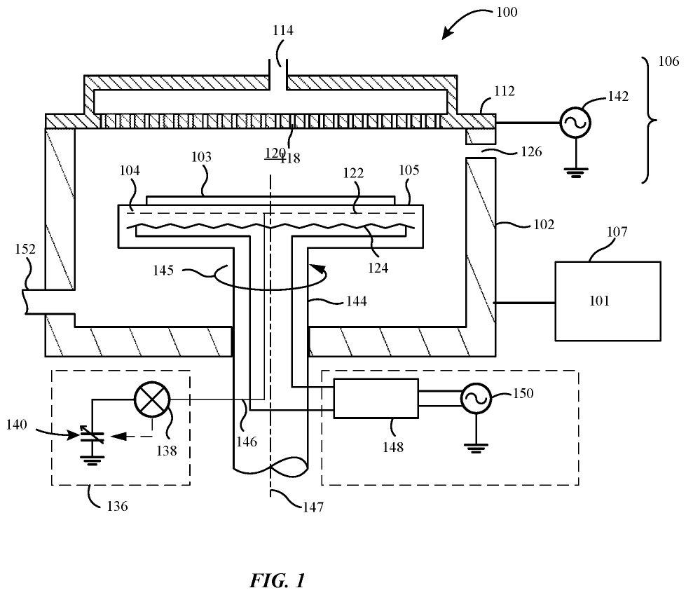

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 144 of the substrate support 104 may be locate, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

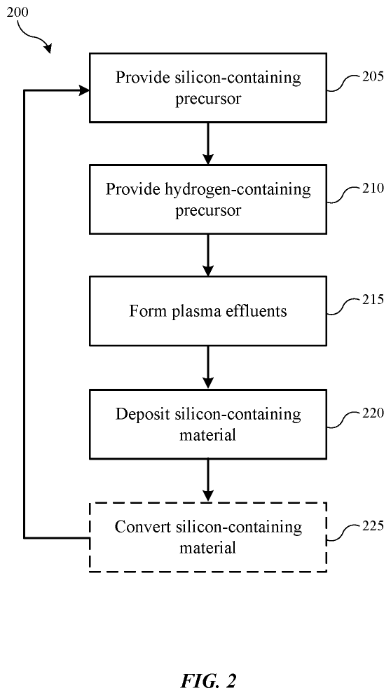

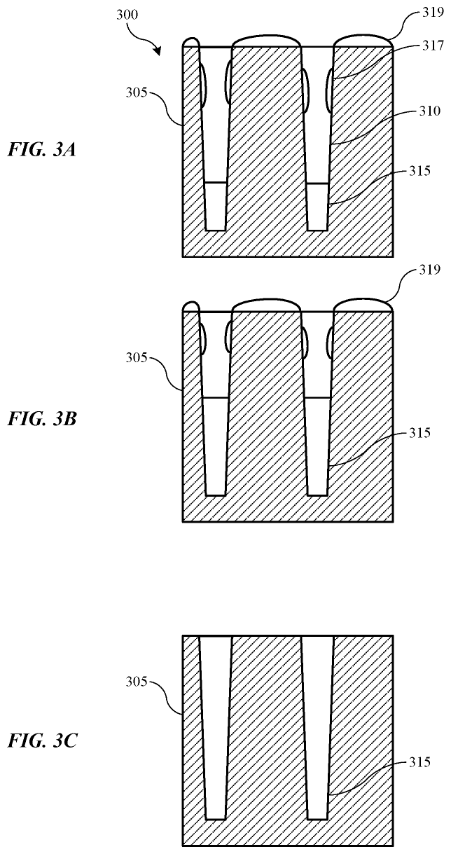

Processing chamber 100 may be utilized in some embodiments of the present technology for processing methods that may include formation, etching, or conversion of materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed with a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a structure 300 may contain any number of additional materials and features having a variety of characteristics and aspects as shown in the figures.

Method 200 may include additional operations prior to initiation of the listed operations. For example, additional processing operations may include forming structures on a semiconductor substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

A substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material in which one or more features 310 may be formed. Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. Features 310 may be characterized by any shape or configuration according to the present technology. In some embodiments, the features 310 may be or include a trench structure or aperture formed within the substrate 305.

Although the features 310 may be characterized by any shapes or sizes, in some embodiments the features 310 may be characterized by higher aspect ratios, or a ratio of a depth of the feature to a width across the feature. For example, in some embodiments, features 310 may be characterized by aspect ratios greater than or about 5:1, and may be characterized by aspect ratios greater than or about 10:1, greater than or about 15:1, greater than or about 20:1, greater than or about 25:1, greater than or about 30:1, greater than or about 40:1, greater than or about 50:1, or greater. Additionally, the features may be characterized by narrow widths or diameters across the feature including between two sidewalls, such as a critical dimension less than or about 50 nm, and may be characterized by a width across the feature of less than or about 45 nm, less than or about 40 nm, less than or about 35 nm, less than or about 30 nm, less than or about 25 nm, or less.

In some embodiments, method 200 may include optional treatment operations, such as a pretreatment, which may be performed to prepare a surface of substrate 305 for deposition. Once prepared, method 200 may include providing one or more precursors to a processing region of the semiconductor processing chamber housing the structure 300. For example, method 200 may include providing a silicon-containing precursor to the processing region at operation 205. At operation 210, a hydrogen-containing precursor may be provided to the processing region. The precursors may also include one or more diluents or carrier gases such as an inert gas or other gas delivered with the silicon-containing precursor and/or the hydrogen-containing precursor. A plasma may be formed of the one or more precursors, including the silicon-containing precursor and the hydrogen-containing precursor, at operation 215. The plasma may be formed within the processing region. For example, in some embodiments a capacitively-coupled plasma may be formed within the processing region by applying a source power to the pedestal supporting the substrate 305 as previously described. In embodiments, method 200 may include applying a bias power to increase directionality of the plasma effluents. Similar to the source power, the bias power may be applied to the pedestal supporting the substrate 305.

A silicon-containing material 315 may be deposited on the substrate 305 at operation 220 from plasma effluents of the silicon-containing precursor. The silicon-containing material 315 may be or include amorphous silicon. The plasma effluents of the silicon-containing precursor may at least partially flow into the features on the substrate to provide a bottom-up type of gap fill. As illustrated in FIG. 3A, silicon-containing material 315 may be deposited on the substrate 305, and may preferentially deposit at a bottom of the trenches or features 310. As illustrated, the silicon-containing material 315 may selectively deposit at the bottom of the feature, although an amount of material may also deposit on the sidewalls of the trenches or features 310 as illustrated with material 317, as well as material on top of, or between, features, as illustrated with material 319. Although the amount deposited may be relatively small, the remaining material on the sidewalls may limit subsequent seam-free and/or void-free deposition. However, the presence of the plasma effluents of the hydrogen-containing precursor may etch material 317 and/or material 319 while deposition of silicon-containing material 315 towards the bottom of the feature 310 in a bottom-up fashion proceeds. Therefore, method 200 may be continued to for a desired duration to allow for a single-step process for gap filling with silicon-containing material 315. As further illustrated in FIGS. 3B-3C, the deposition may continue with material illustrated as material 317 and/or material 319 being removed during the deposition of the material in a bottom-up fashion without the formation of a gap or seam in the silicon-containing material 315, and without pinching off of the feature 310. Accordingly, a single deposition operation may fill the feature without cycling the deposition with etch operations commonly used in conventional technologies.

Method 200 may also optionally include converting the silicon-containing material 315 to another to another material at optional operation 225. For example, subsequent to the depositing the silicon-containing material 315 at operation 220, one or more conversion precursors may be providing to the processing region of the semiconductor processing chamber. For example, a nitrogen-containing precursor, an oxygen-containing precursor, and/or a carbon-containing precursor may be provided to the processing region of the chamber, along with any carrier or diluent gases. A plasma may be formed of the conversion precursor(s), which may then contact the silicon-containing material 315 within the feature 310. The plasma effluents of the conversion precursor may interact with the silicon-containing material 315 within the feature 310, and convert the silicon-containing material 315 to a silicon-and-oxygen-containing material, a silicon-and-carbon-containing material, or a silicon-and-nitrogen-containing material such as silicon nitride, silicon oxide, silicon carbide, silicon oxynitride, silicon oxycarbide, silicon carbon nitride, or silicon oxycarbonitride, along with any other silicon-containing materials.

Any number of precursors may be used with the present technology with regard to the silicon-containing precursor and hydrogen-containing precursor used during method 200. Silicon-containing precursors that may be used may include, but are not limited to, silane (SiH₄), disilane (Si₂H₆), trisilane (Si₃H₈), or other organosilanes including cyclohexasilanes, silicon tetrafluoride (SiF₄), silicon tetrachloride (SiCl₄), dichlorosilane (SiH₂Cl₂), tetraethyl orthosilicate (TEOS), as well as any other silicon-containing precursors that may be used in silicon-containing material deposition. The silicon-containing material may be nitrogen-free, oxygen-free, and/or carbon-free in some embodiments. Hydrogen-containing precursors that may be used may include, but are not limited to, diatomic hydrogen (H₂), steam (H₂O), ammonia (NH₃), diimide (N₂H₂), hydrazine (N₂H₄) as well as any other hydrogen-containing precursors that may be used in silicon-containing material 315 formation, or other etching of silicon-containing material 315. In any of the operations of method 200, one or more additional precursors may be included, such as inert precursors, which may include Ar, He, Xe, Kr, or other materials such as nitrogen, ammonia, hydrogen, or other precursors to help with dissociation and/or dilution of the precursors. In embodiments, the processing region may be maintained halogen-free while depositing the silicon-containing material 315 on the substrate.

A flow rate ratio of the silicon-containing precursor relative to the hydrogen-containing precursor may be maintained to balance deposition rate with the removal of material on the sidewall and top of the feature. A reduced flow rate ratio may provide more hydrogen for etching material and removing material preventing seam-free gap fill without pinching off at the top of the feature. However, a reduced flow rate ratio may also reduce deposition rate and overall throughput. For example, the flow rate ratio of the silicon-containing precursor relative to the hydrogen-containing precursor may be less than or about 1:8, and the flow rate ratio may be less than or about 1:9, less than or about 1:10, less than or about 1:15, less than or about 1:20, less than or about 1:25, less than or about 1:30, less than or about 1:35, less than or about 1:40, less than or about 1:45, less than or about 1:50, less than or about 1:75, less than or about 1:100, or less.

In embodiments, a flow rate of the silicon-containing precursor may be less than or about 500 sccm, and may be less than or about 450 sccm, less than or about 400 sccm, less than or about 350 sccm, less than or about 300 sccm, less than or about 250 sccm, less than or about 200 sccm, less than or about 150 sccm, less than or about 100 sccm, less than or about 75 sccm, less than or about 50 sccm, less than or about 40 sccm, less than or about 30 sccm, less than or about 25 sccm, less than or about 20 sccm, less than or about 15 sccm, less than or about 10 sccm, or less. A flow rate of the hydrogen-containing precursor may be greater than or about 1,000 sccm, and may be greater than or about 1,250 sccm, greater than or about 1,500 sccm, greater than or about 1,750 sccm, greater than or about 2,000 sccm, or more.

In embodiments, the source power may be applied through the substrate support or pedestal although it is contemplated that source power may additionally or alternatively be provided via other semiconductor processing chamber components, such as the faceplate or showerhead. The source power applied during method 200 may be a lower power plasma, which may limit dissociation and the resultant deposition rate. The controlled dissociation and deposition rate may provide bottom-up gap filling of both seam-free and void-free silicon-containing material 315.

In embodiments, the source power may be provided in a continuous wave. However, it is contemplated that the source power could also be pulsed to reduce the effective plasma power. The source power may be applied at any higher frequency, such as greater than or about 10 MHz, greater than or about 13 MHZ, such as 13.56 MHz, greater than or about 15 MHz, or higher. The source power may deliver a plasma power to the substrate support or pedestal at less than or about 500 W, and may deliver a plasma power of less than or about 450 W, less than or about 400 W, less than or about 350 W, less than or about 300 W, less than or about 250 W, less than or about 200 W, less than or about 125 W, less than or about 150 W, less than or about 175 W, less than or about 100 W, less than or about 50 W, or less.

By utilizing a bias power, the deposition plasma may be characterized by an increased energy, which may further dissociate the silicon-containing precursor and/or hydrogen-containing precursor. Additionally, the bias power may result in some sputtering of the deposited material, such as material 317 and/or material 319, as well as crystalized silicon-containing material 315. However, at increased bias power, the plasma effluents may begin bombarding the deposited silicon-containing material 315 and cause crystallization. Therefore, a tuned amount of bias power may result in the removal of crystalized material and the prevention of crystallization of amorphous material. In embodiments, the bias power may be greater than or about a source power used to form plasma effluents of the silicon-containing precursor and the hydrogen-containing precursor. For example, the bias power may be greater than or about 250 W, and may be greater than or about 300 W, greater than or about 350 W, greater than or about 400 W, greater than or about 500 W, greater than or about 600 W, greater than or about 700 W, greater than or about 800 W, greater than or 900 W, greater than or about 1,000 W, or more. However, to prevent crystallization as previously discussed, the bias power may also be less than or about 2,000 W, and may be less than or about 1,750 W, less than or about 1,500 W, less than or about 1,250 W, less than or about 1,000 W, or less.

The bias power may be pulsed, and the duty cycle may be reduced, which may further reduce the effective bias power in some embodiments. For example, bias power source may be operated at a lower frequency than the source power, and may be operated at less than or about 10 MHz, less than or about 5 MHz, less than or about 2 MHz, or less. The bias power may create an amount of directionality of plasma effluent movement. The lower frequency power may also impart additional energy to the ions as they travel in more straight-line paths down to the substrate. Additionally, the pulsing duty cycle may be applied at less than or about 50%, and may be applied at less than or about 40%, less than or about 30%, less than or about 25%, less than or about 20%, less than or about 15%, less than or about 10%, less than or about 5%, less than or about 1% or less. This may limit the effective bias power which may reduce bombardment and possibility of crystallization of the silicon-containing material 315. Further, the bias power may be pulsed at a frequency of, for example, between about 10 Hz and about 10 kHz.

Pressure may impact operations of the present technology. Pressure within the chamber may be kept relatively low to permit better gap fill. More specifically, lower pressure may result in reduced scattering of the plasma effluents and, therefore, increased angular deposition for a more directional deposition. In embodiments, pressure within the semiconductor processing chamber may be maintained at less than or about 10 Torr, and may be maintained at less than or about 8 Torr, less than or about 6 Torr, less than or about 5 Torr, less than or about 4 Torr, less than or about 3 Torr, less than or about 2 Torr, less than or about 1 Torr, less than or about 0.5 Torr, or less. By performing processes according to some embodiments of the present technology, improved fill of narrow features utilizing silicon-containing materials may be produced.

Temperature may also impact operations of the present technology. For example, in some embodiments to facilitate deposition, the method 200 may be performed at a temperature below or about 150° C., and may be performed at a temperature less than or about 140° C., less than or about 130° C., less than or about 120° C., less than or about 110° C., less than or about 100° C., less than or about 90° C., less than or about 80° C., or lower. The temperature may be maintained in any of these ranges throughout the method 200.

Method 200 may allow silicon-containing material 315 to be deposited at the bottom of the feature 310 relative to the sidewall of the feature 310 at a ratio greater than or about 1:10, such as greater than or about 1:20, greater than or about 1:50, greater than or about 1:100, or more. In embodiments, the deposition of silicon-containing material 315 at the bottom of the feature 310 relative to the sidewall of the feature 310 may be infinite due to eliminated deposition on the sidewall of the feature 310.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor to a processing region of a semiconductor processing chamber, wherein a substrate comprising one or more features is housed within the processing region;
providing a hydrogen-containing precursor to the processing region of the semiconductor processing chamber;
forming plasma effluents of the silicon-containing precursor and the hydrogen-containing precursor; and
depositing a silicon-containing material on the substrate, wherein the silicon-containing material extends into the one or more features.

2. The semiconductor processing method of claim 1, wherein the silicon-containing precursor comprises silane (SiH₄), disilane (Si₂H₆), or trisilane (Si₃H₈).

3. The semiconductor processing method of claim 1, wherein the one or more features are characterized by a critical dimension of less than or about 50 nm.

4. The semiconductor processing method of claim 1, wherein the hydrogen-containing precursor comprises diatomic hydrogen (H₂).

5. The semiconductor processing method of claim 1, wherein a flow rate ratio of the silicon-containing precursor relative to the hydrogen-containing precursor is less than or about 1:8.

6. The semiconductor processing method of claim 1, wherein the plasma effluents of the silicon-containing precursor and the hydrogen-containing precursor are formed at a plasma power of less than or about 500 W.

7. The semiconductor processing method of claim 1, further comprising:
applying a bias power while forming plasma effluents of the silicon-containing precursor and the hydrogen-containing precursor, while depositing the silicon-containing material on the substrate, or both.

8. The semiconductor processing method of claim 7, wherein the bias power is greater than or about 250 W.

9. The semiconductor processing method of claim 1, wherein the silicon-containing material is amorphous silicon.

10. The semiconductor processing method of claim 1, wherein a pressure in the semiconductor processing chamber is maintained at less than or about 5 Torr.

11. A semiconductor processing method comprising:
providing a silicon-containing precursor to a processing region of a semiconductor processing chamber, wherein a substrate comprising one or more features is housed within the processing region;
providing a hydrogen-containing precursor to the processing region of the semiconductor processing chamber, wherein a flow rate ratio of the silicon-containing precursor relative to the hydrogen-containing precursor is less than or about 1:8;
forming plasma effluents of the silicon-containing precursor and the hydrogen-containing precursor; and
depositing a silicon-containing material on the substrate, wherein the silicon-containing material extends into the one or more features.

12. The semiconductor processing method of claim 11, wherein a flow rate of the silicon-containing precursor is less than or about 400 sccm.

13. The semiconductor processing method of claim 11, wherein forming plasma effluents of the silicon-containing precursor and the hydrogen-containing precursor comprises applying a source power to a pedestal supporting the substrate.

14. The semiconductor processing method of claim 11, further comprising:
applying a bias power to a pedestal supporting the substrate, wherein the bias power is pulsed at a duty cycle less than or about 25%.

15. The semiconductor processing method of claim 11, further comprising:
etching silicon-containing material from sidewalls of the one or more features with the plasma effluents of the hydrogen-containing precursor while depositing the silicon-containing material on the substrate.

16. The semiconductor processing method of claim 15, wherein depositing the silicon-containing material on the substrate fills the one or more features in a single operation.

17. The semiconductor processing method of claim 15, further comprising:
converting the silicon-containing material to a silicon-and-oxygen-containing material, a silicon-and-carbon-containing material, or a silicon-and-nitrogen-containing material.

18. A semiconductor processing method comprising:
providing a silicon-containing precursor to a processing region of a semiconductor processing chamber, wherein a substrate comprising one or more features is housed within the processing region;
providing a hydrogen-containing precursor to the processing region of the semiconductor processing chamber;
forming plasma effluents of the silicon-containing precursor and the hydrogen-containing precursor;
applying a bias power to a pedestal supporting the substrate; and
depositing amorphous silicon on the substrate, wherein the amorphous silicon extends into the one or more features.

19. The semiconductor processing method of claim 18, wherein the bias power is greater than or about a source power used to form plasma effluents of the silicon-containing precursor and the hydrogen-containing precursor.

20. The semiconductor processing method of claim 18, wherein the processing region is maintained halogen-free while depositing the amorphous silicon on the substrate.
